(19) United States
(12) Patent Application Publication
(10) Pub. No.: US 2010/0025793 A1
(43) Pub. Date: Feb. 4, 2010

(54) Assembly for image sensing chip and assembling method thereof

(75) Inventors: Chia-Shuai Chang, Tao-Yuan Hsien (TW); Chia-Ming Wu, Tao-Yuan Hsien (TW)

Correspondence Address: BACON & THOMAS, PLLC, 625 SLATERS LANE, FOURTH FLOOR, ALEXANDRIA, VA, 22314-1176, US

(73) Assignee: Impac Technology Co., Ltd., Tao-Yuan Hsien (TW)

(21) Appl. No.: 12/222,094

(22) Filed: Aug. 1, 2008

(51) Int. Cl. H01L 33/00; H01J 5/02; H05K 3/30

(52) U.S. Cl. 257/433; 250/239; 29/832; 257/E33.058

(57) ABSTRACT

An assembly for an image sensing chip to reduce the entire thickness and an assembling method thereof are disclosed. Meanwhile, the electro-optical assembly includes an image sensing chip; and a multi-layer printed circuit board having a recess to accommodate the image sensing chip, thereby decreasing the entire electro-optical assembly in thickness. The image sensing chip further includes a holder mounted on the multi-layer printed circuit board for protecting the image sensing chip and a lens mounted on the holder for being pervious to light.

### FIELD OF THE INVENTION

The present invention relates to an assembly of an image sensing chip and an assembling method thereof, and more particularly, to an assembly of an image sensing chip for reducing the entire thickness thereof and an assembling method thereof.

### BACKGROUND OF THE INVENTION

In recent years, image sensing chips have been widely applied to electronic products for converting light into electrical signals. The applications of image sensor components include monitors, cell phones, scanners, digital cameras, and so on.

Conventionally, these electro-optical modules have been packaged for use by mounting them to a substrate and enclosing them within a housing assembly. The housing assembly incorporates a transparent lid to allow light or other forms of radiation to be received by the sensor. The lid may be a flat window or shaped as a lens to provide optical properties. The substrate and housing are often formed from a ceramic material, and the lid is glass or a similar transparent substance attached to the housing by an adhesive. Due to the materials and structure involved, this packaging technique may be expensive and difficult to manufacture. Further, growing desire for portable electronic devices withstanding extreme environments raises concerns of durability and size. As well known, electro-optical modules can be used to convert electrical signals into optical signals and vice versa. Many different types of electro-optical modules are presently being manufactured. These electro-optical modules have many applications, particularly within monitors, cell phones, scanners, digital cameras, and so on, and can range in cost from under a hundred dollars to many thousands of dollars per module, depending on their application and functionality. When electro-optical modules are introduced into an electrical system, the electrical system often uses a number of integrated circuits which are mounted on a printed circuit board. Each integrated circuit includes a number of leads extending from the packaging of the circuit. The leads of the various integrated circuits are interconnected to allow signals to be passed between the integrated circuits such that the system performs some function.

A limitation of the prior art is the lack of flexibility in the assembly of printed circuit boards. Because the electro-optical modules must be mounted during assembly of the printed circuit board, there is no flexibility in adding any of these elements or adjusting their positions once the printed circuit board has been fabricated. Furthermore, as the entire apparatus decreases in thickness and size, the electro-optical module installed in the entire apparatus should be miniaturized. What is therefore required is an electro-optical module design that makes it possible to reduce the thickness of a component of the electro-optical module and to minimize the assembly space in the electro-optical module.

Please refer to FIG. 1. It illustrates an electro-optical module mounted on a printed circuit board according to the prior art. As shown in FIG. 1, the electro-optical module 11 is mounted on the surface of the printed circuit board 12. Meanwhile, the entire assembly of the electro-optical module 11 and the printed circuit board 12 has the entire thickness including the thickness TA of the electro-optical module 11 and the thickness TB of the printed circuit board 12. Even though the electro-optical module design makes it possible to reduce the thickness of a component of the electro-optical module and to minimize the assembly space in the electro-optical module, the entire assembly still has the entire thickness equal to the thickness TA of the electro-optical module 11 plus the thickness TB of the printed circuit board 12.

Please refer to FIG. 2. It illustrates another electro-optical module mounted on a printed circuit board according to the prior art. As shown in FIG. 2, the electro-optical module 21 is mounted on the surface of the printed circuit board 12. In comparison between the electro-optical module 21 of FIG. 2 and the electro-optical module 11 of FIG. 1, the thickness TA′ of the electro-optical module 21 is thinner than the thickness TA of the electro-optical module 11. However, the entire assembly of FIG. 2 still has the entire thickness equal to the thickness TA′ of the electro-optical module 21 plus the thickness TB of the printed circuit board 12.

Although several assembling methods of the prior art are technically feasible, in practice the entire assembly can't be miniaturized effectively. Meanwhile, the entire thickness of the assembly can't be further decreased by means of assembling the electro-optical module with the printed circuit board in a specific thickness according to the prior art. The prior arts fail to disclose an assembly of the electro-optical module and the printed circuit board having an entire thickness less than the thickness of the electro-optical module plus that of the printed circuit board. Therefore, it needs to provide an assembly of an image sensing chip for reducing the entire thickness thereof, thereby decreasing the assembly in thickness and size and overcoming the lack of flexibility in the assembly of printed circuit boards.

### SUMMARY OF THE INVENTION

This paragraph extracts and compiles some features of the present invention; other features will be disclosed in the follow-up paragraph. It is intended to cover various modifications and similar arrangements included within the spirit and scope of the appended claims.

In accordance with an aspect of the present invention, an electro-optical assembly includes an image sensing chip, and a multi-layer printed circuit board having a recess to accommodate the image sensing chip, thereby decreasing the entire electro-optical assembly in thickness. Thus, the assembly of the present invention could reduce the entire thickness of the electro-optical module plus the printed circuit boards.

Preferably, the electro-optical assembly can further include a holder mounted on the multi-layer printed circuit board for protecting the image sensing chip and a lens mounted on the holder for being pervious to light.

Preferably, the image sensing chip is disposed in the recess by means of chip-on-board (COB) packaging, chip scale packaging (CSP) or surface mount technology (SMT).

Preferably, the image sensing chip has a plurality of bonding wires electrically connected to the multi-layer printed circuit board.

Preferably, the image sensing chip includes complementary metal oxide semiconductor (CMOS) image sensor or charge coupled device (CCD) image sensor.

It is another object of the present invention to provide an assembling method of an image sensing chip mounted on a printed circuit board for reducing the entire thickness thereof. Meanwhile, the assembling method for an electro-optical assembly, including the steps of a) providing a multi-layer printed circuit board having a recess to accommodate an image sensing chip; and b) disposing the image sensing chip into the recess of the multi-layer printed circuit board, thereby decreasing the entire electro-optical assembly in thickness.

Preferably, the step b) further includes the steps of b1) electrically conducting the image sensing chip to the multi-layer printed circuit board; b2) mounting a holder above the image sensing chip on the multi-layer printed circuit board for protecting the image sensing chip; and b3) mounting a lens on the holder for being pervious to light.

Preferably, the image sensing chip is disposed in the recess by means of chip-on-board (COB) packaging, chip scale packaging (CSP) or surface mount technology (SMT).

Preferably, the image sensing chip is conducted to the multi-layer printed circuit board via a plurality of bonding wires.

Preferably, the image sensing chip includes complementary metal oxide semiconductor (CMOS) image sensor or charge coupled device (CCD) image sensor.

### BRIEF DESCRIPTION OF THE DRAWING

The above objects and advantages of the present invention will become more readily apparent to those ordinarily skilled in the art after reviewing the following detailed description and accompanying drawings, in which:

FIG. 1 illustrates an electro-optical module mounted on a printed circuit board according to the prior art;

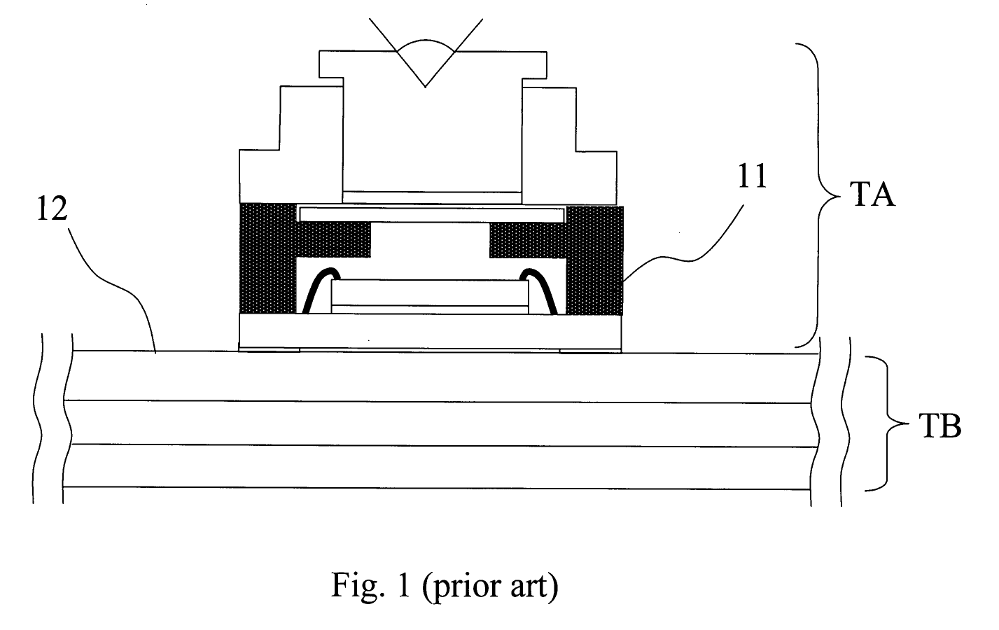

FIG. 2 illustrates another electro-optical module mounted on a printed circuit board according to the prior art;

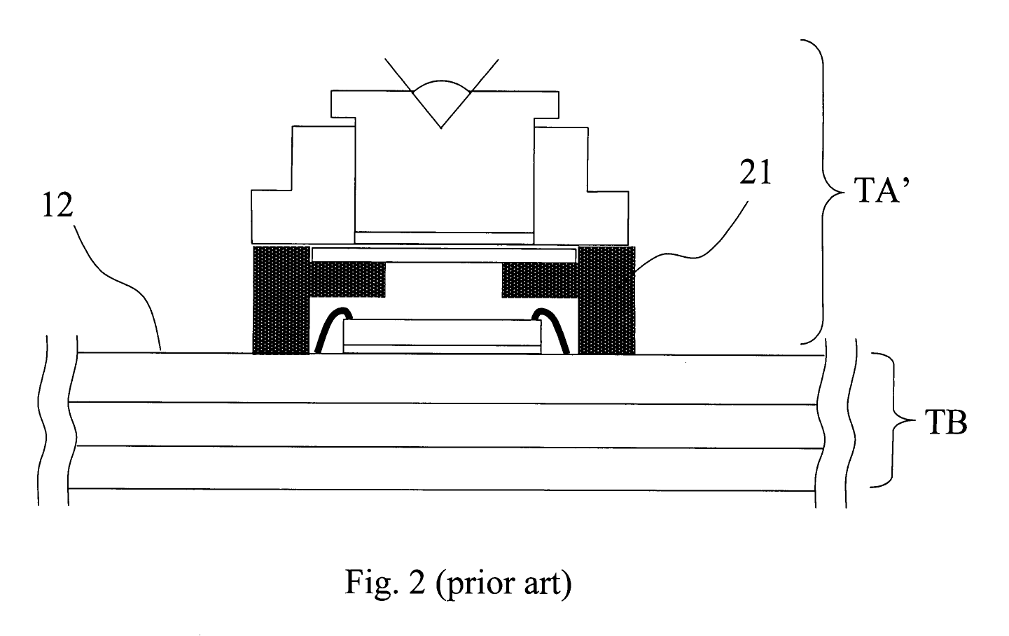

FIG. 3 illustrates a first embodiment of the electro-optical assembly according to the present invention;

FIG. 4 illustrates a second embodiment of the electro-optical assembly according to the present invention;

FIG. 5 illustrates a third embodiment of the electro-optical assembly according to the present invention;

FIG. 6 illustrates a fourth embodiment of the electro-optical assembly according to the present invention; and

FIG. 7 illustrates a fifth embodiment of the electro-optical assembly according to the present invention.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

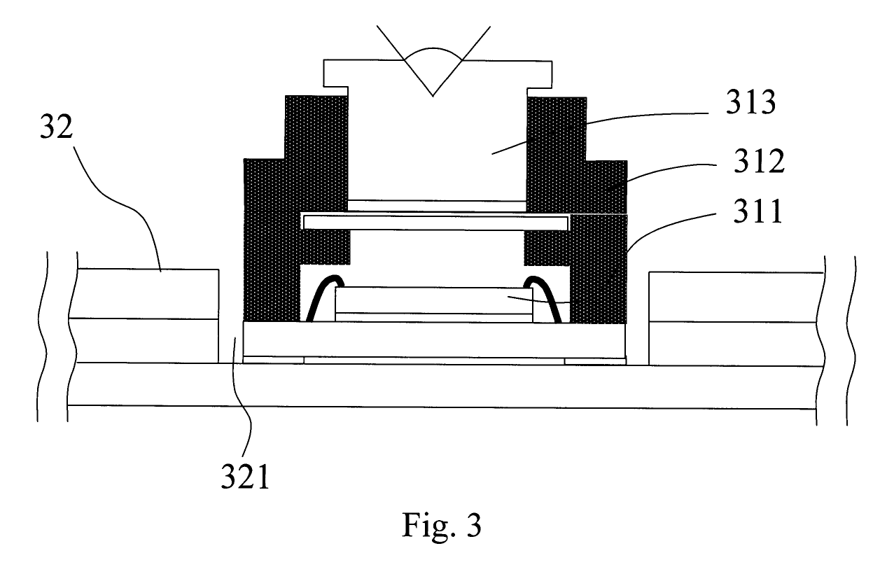

Please refer to FIG. 3. It illustrates a first embodiment of an electro-optical assembly according to the present invention. As shown in FIG. 3, the electro-optical assembly includes a multi-layer printed circuit board 32 having a recess 321; and an image sensing chip 311. The recess 321 is to accommodate the image sensing chip 311, thereby decreasing the entire electro-optical assembly in thickness.

In this embodiment, the electro-optical assembly including the image sensing chip 311 and a holder 312 is disposed in the recess 321 of the multi-layer printed circuit board 32. The holder 312 is for protecting the image sensing chip 311. Furthermore, a lens 313 is mounted on the holder 312 for being pervious to light. The image sensing chip 311 could be complementary metal oxide semiconductor (CMOS) image sensor or charge coupled device (CCD) image sensor.

The electro-optical assembly can be disposed in the recess 321 by different methods, such as chip-on-board (COB) packaging, chip scale packaging (CSP) or surface mount technology (SMT).

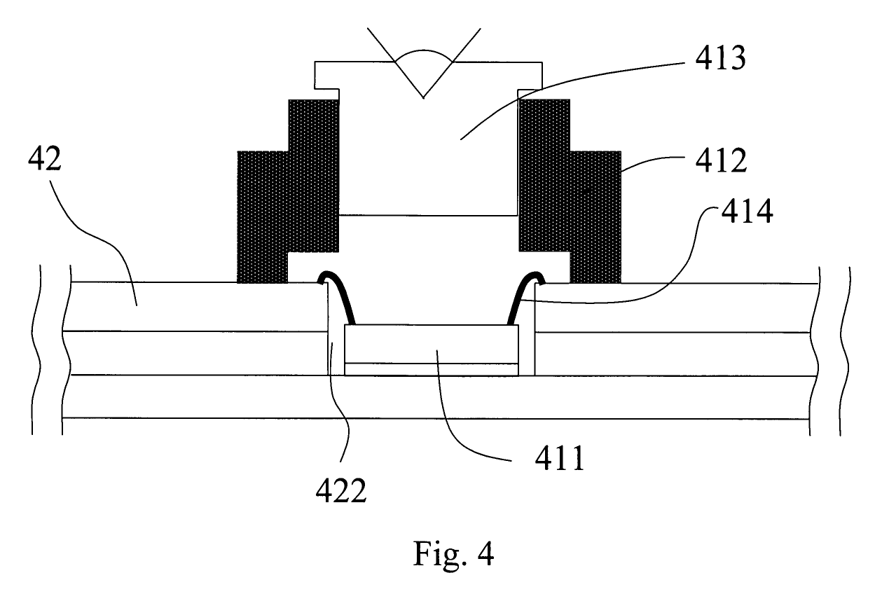

Please refer to FIG. 4. It illustrates a second embodiment of an electro-optical assembly according to the present invention. As shown in FIG. 4, the electro-optical assembly includes an image sensing chip 411; a holder 412 for protecting the image sensing chip 411; a multi-layer printed circuit board 42 having a recess 422 for accommodating the image sensing chip 411; and a lens 413 mounted on the holder 412 for being pervious to light. Different from the first embodiment, the image sensing chip 411 is disposed in the recess 422, while the holder 412 is disposed on the multi-layer printed circuit board 42. Due to the fact that the image sensing chip 411 is disposed in the recess 422, the holder 412 dose not need to be thick or tall, and therefore, the thickness of the entire electro-optical assembly can be reduced.

In this embodiment, the image sensing chip 411 is disposed in the recess 422 of the multi-layer printed circuit board 42 by means of chip-on-board (COB) packaging. The image sensing chip 411 is electrically connected to the multi-layer printed circuit board 42 via bonding wires 414. The image sensing chip 411 could be complementary metal oxide semiconductor (CMOS) image sensor or charge coupled device (CCD) image sensor.

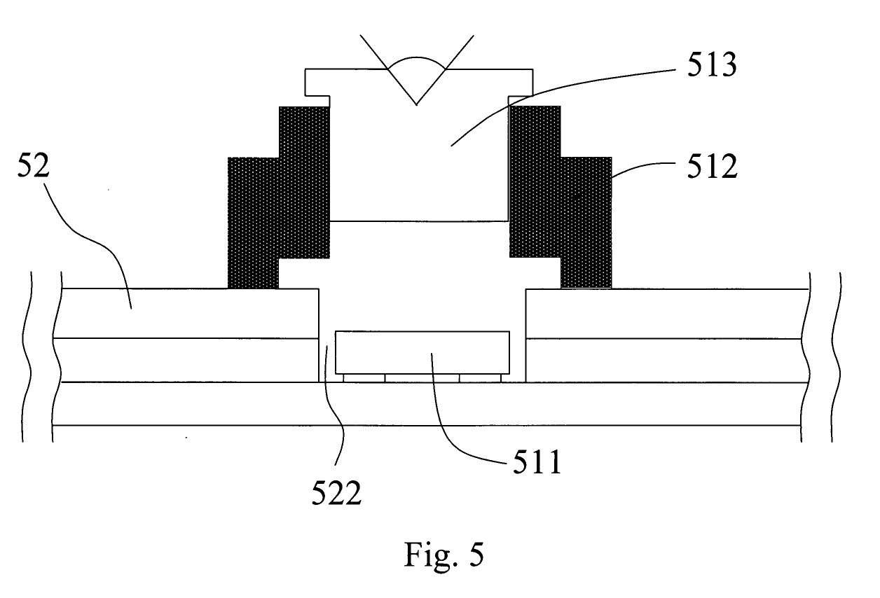

Please refer to FIG. 5. It illustrates a third embodiment of an electro-optical assembly according to the present invention. As shown in FIG. 5, the electro-optical assembly includes an image sensing chip 511, a holder 512 for protecting the chip 511, a lens 513 mounted on the holder 512 for being pervious to light, and a multi-layer printed circuit board 52 having a recess 522 to accommodate the image sensing chip 511. Different from the second embodiment, the image sensing chip 511 of this embodiment is disposed in the recess 522 and mounted on the multi-layer printed circuit board by means of surface mount technology (SMT). Accordingly, the thickness of the entire electro-optical assembly is reduced.

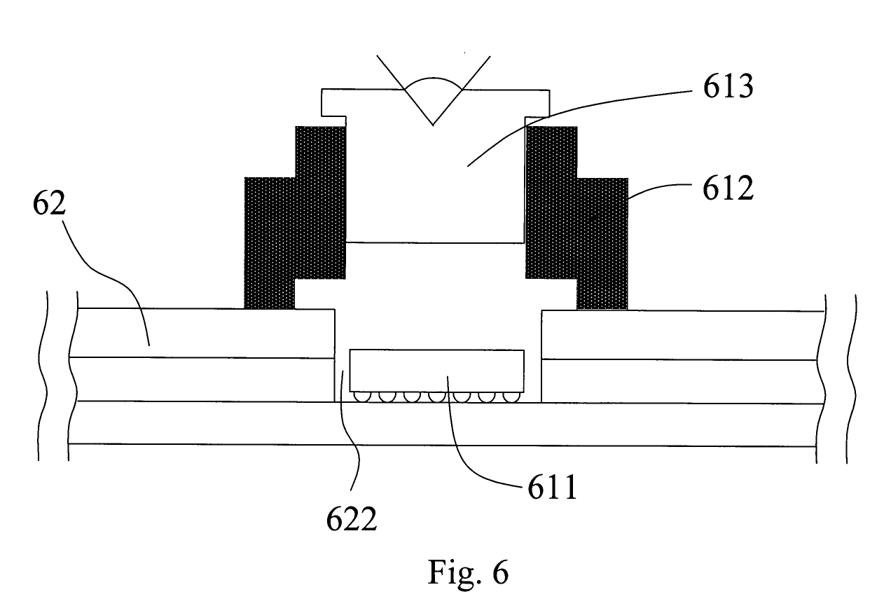

FIG. 6 illustrates a fourth embodiment of an electro-optical assembly according to the present invention. As shown in FIG. 6, the electro-optical assembly includes an image sensing chip 611, a holder 612 for protecting the image sensing chip 611, a lens 613 mounted on the holder 612 for being pervious to light, and a multi-layer printed circuit board 62 having a recess 622 to accommodate the chip 611. Different from the above mentioned embodiments, the image sensing chip 611 is a flip chip and is disposed in the recess 622 by means of chip scale package (CSP).

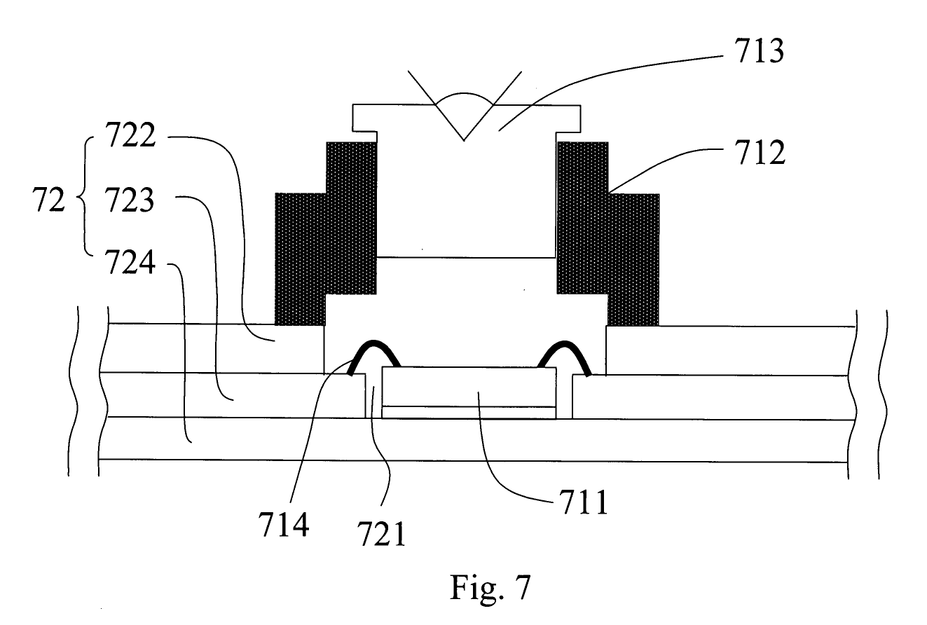

Please refer to FIG. 7. It illustrates a fifth embodiment of an electro-optical assembly according to the present invention. As shown in FIG. 7, the electro-optical assembly of the present could include at least an image sensing chip 711, a holder 712 for protecting the chip 711, a lens 713 mounted on the holder 712 for being pervious to light, and a multi-layer printed circuit board 72 having a recess 721 for accommodating the image sensing chip 711. In this embodiment, the multi-layer printed circuit board 72 of the present invention has three layers 722˜724. The image sensing chip 711 is disposed in the recess 721 and placed on top of layer 724 by means of chip-on-board (COB) packaging. Meanwhile, the image sensing chip 711 has bonding wires 714 electrically connected to layer 723. On the other hand, the holder 712 of the present invention is mounted on layer 722. The holder 712 is disposed on layer 722 for further saving the cost of materials thereof and decreasing the occupied space in the electro-optical assembly.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. An electro-optical assembly, comprising:
an image sensing chip; and
a multi-layer printed circuit board having a recess to accommodate said image sensing chip, thereby decreasing the entire electro-optical assembly in thickness.

2. The electro-optical assembly according to claim 1, further comprising a holder mounted on said multi-layer printed circuit board for protecting said image sensing chip and a lens mounted on said holder for being pervious to light.

3. The electro-optical assembly according to claim 1, wherein said image sensing chip is disposed in said recess by means of chip-on-board (COB) packaging, chip scale packaging (CSP) or surface mount technology (SMT).

4. The electro-optical assembly according to claim 1, wherein said image sensing chip has a plurality of bonding wires electrically connected to said multi-layer printed circuit board.

5. The electro-optical assembly according to claim 1, wherein said image sensing chip comprises complementary metal oxide semiconductor (CMOS) image sensor or charge coupled device (CCD) image sensor.

6. An assembling method for an electro-optical assembly, comprising the steps of:
a) providing a multi-layer printed circuit board having a recess to accommodate an image sensing chip; and
b) disposing said image sensing chip into said recess of said multi-layer printed circuit board, thereby decreasing the entire electro-optical assembly in thickness.

7. The assembling method according to claim 6, wherein said step b) further comprises the steps of:
b1) electrically conducting said image sensing chip to said multi-layer printed circuit board;
b2) mounting a holder above said image sensing chip on said multi-layer printed circuit board for protecting said image sensing chip; and
b3) mounting a lens on said holder for being pervious to light.

8. The assembling method according to claim 6, wherein said image sensing chip is disposed in said recess by means of chip-on-board (COB) packaging, chip scale packaging (CSP) or surface mount technology (SMT).

9. The assembling method according to claim 7, wherein said image sensing chip is conducted to said multi-layer printed circuit board via a plurality of bonding wires.

10. The assembling method according to claim 6, wherein said image sensing chip comprises complementary metal oxide semiconductor (CMOS) image sensor or charge coupled device (CCD) image sensor.
